(19) United States
(12) Patent Application Publication
(10) Pub. No.: US 2005/0178662 A1
(43) Pub. Date: Aug. 18, 2005

(54) Rotating tubular cathode

(76) Inventor: Dieter Wurczinger, Bad Vilbel (DE)

Correspondence Address: Koda & Androlia, 2029 Century Park East, Suite 1140, Los Angeles, CA, 90067-2983, US

(21) Appl. No.: 10/508,475

(22) PCT Filed: Mar. 19, 2003
(86) PCT No.: PCT/DE03/00903

(30) Foreign Application Priority Data
Mar. 22, 2002 (DE) 102 13 049.3

(51) Int. Cl. C23C 14/35

(52) U.S. Cl. 204/298.21; 204/298.22

(57) ABSTRACT

The invention relates to a rotatable tube cathode (2) for sputter installations, in which, for example, window panes are coated. This tube cathode (2) comprises in conventional manner a fluid cooling system (4, 5). In order for [the tube cathode] to be more readily exchanged, a cylindrical and elastic film (36) is provided between the target (30), disposed on the circumference of the tube cathode, or the target carrier and the central longitudinal axis of the tube cathode (2). This film (36) seals the fluid circulation with respect to the target (30) and therewith forms a closed system.

The invention relates to a tube cathode according to the preamble of patent claim 1.

For coating substrates of larger dimensions, for example window panes or windshield panes, sputter installations comprising planar magnetrons have already been used for some time.

Due to the large areas which must be coated, the sputter installations also have large dimensions.

Instead of planar magnetrons, rotating cylindrical magnetrons have also already been proposed for use in sputter installations. In the case of rotational magnetrons the material to be sputtered, referred to as target, is developed in the form of a tube. During sputtering the target tube rotates about the magnets disposed in the tube, which do not take part in the rotation of the target tube. Compared to planar magnetrons, the advantage of rotational magnetrons consists in that, instead of a target yield of only approximately 20% to 40%, a yield of approximately 90% is obtained. However, it is not exactly simple to rotate a cylindrical target in high vacuum and, in addition, to provide water cooling and a stationary magnetic field. Problems are especially encountered during magnetron or cathode exchange, which consist in having to seal the cooling water with respect to a vacuum, which is extremely difficult in rotating systems.

From EP 0 500 774 B1 a rotatable cylindrical magnetron with a target is already known, which has a magnet structure extending over the full length of the magnetron and secured against joint rotation with the target. Herein a multiplicity of rollers is provided on the magnet structure which is stayed on an inner surface of the target. The cooling is here accomplished by a cooling means line disposed within the target structure and extending over its length. The cooling means line is secured in place against rotation by the connection with the housing of the vacuum chamber. Of disadvantage is here that the target itself is only partially cooled.

A sputter device with rotating target and a water target-cooling system is furthermore known (DE 41 17 368 A1). In this case the cooling is concentrated on the region(s) of the target which during operation are especially heated. For example the magnets of the magnetron form at least one cooling channel of the sputter device. Alternatively, its own cooling tube is provided, which comprises several cooling channels and with its outer wall abuts the inner wall of the target carrier. While the latter alternative does indeed cool the entire target and not only the magnets, it is difficult, however, to fit a new target with target carrier onto the cooling tube.

A device is furthermore known with which it becomes possible to affix a rotatable cylindrical magnetron target with a spindle (U.S. Pat. No. 5,591,314). With the aid of this device the disadvantages of known rotating cathode facilities are intended to be eliminated. These disadvantages consist in the breach of cooling water at the interface between the cylindrical magnetron target and the drive spindle. The device comprises a collar provided with threads, which extends into convolutions on the outside of the target, with a single water-to-vacuum seal provided at the interface between target and spindle.

The invention addresses the problem of simplifying the exchange of tube cathodes in sputter installations.

This problem is solved according to the characteristics of patent claim 1.

The cooling of the target tube takes place via a flexible fluid-cooled film, which comes into contact with the target tube from the inside. The film seals the fluid-circulation with respect to the target tube and therewith forms a closed system. In this case there is no direct fluid-vacuum transition which must be mounted or dismounted when exchanging the target. The consumed target tube is simply removed and replaced by a new one. Consequently, the target exchange can be completed very rapidly without presenting any sealing problems.

A further advantage of the invention comprises that the target tube can be implemented very simply, since no elaborate connection techniques are required.

An embodiment example of the invention is shown in the drawing and will be described in further detail in the following. In the drawing depict:

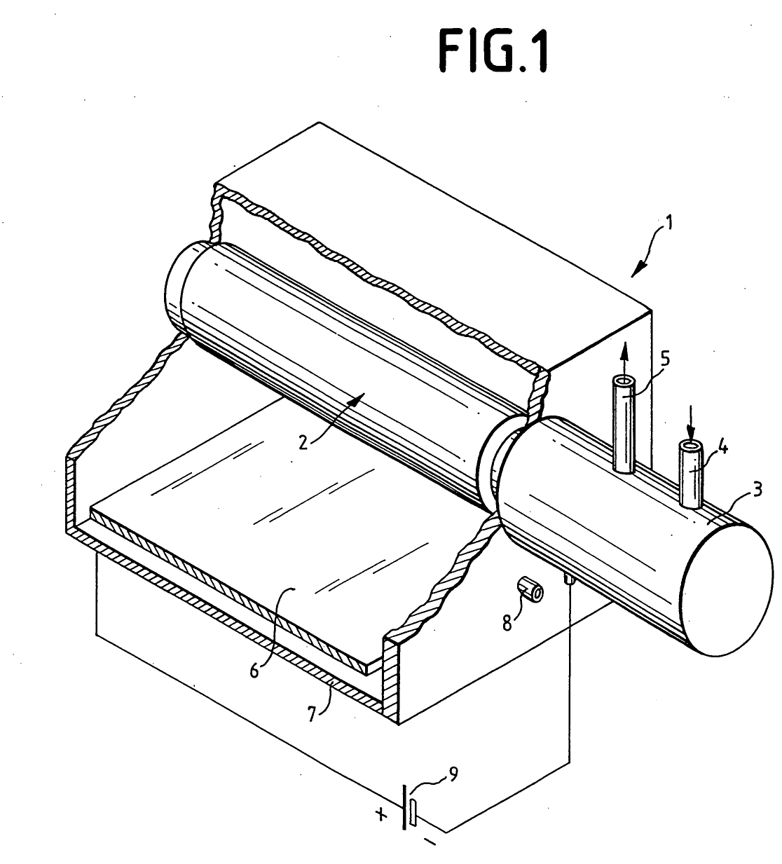

FIG. 1 a schematic representation of a coating installation with a rotating cathode,

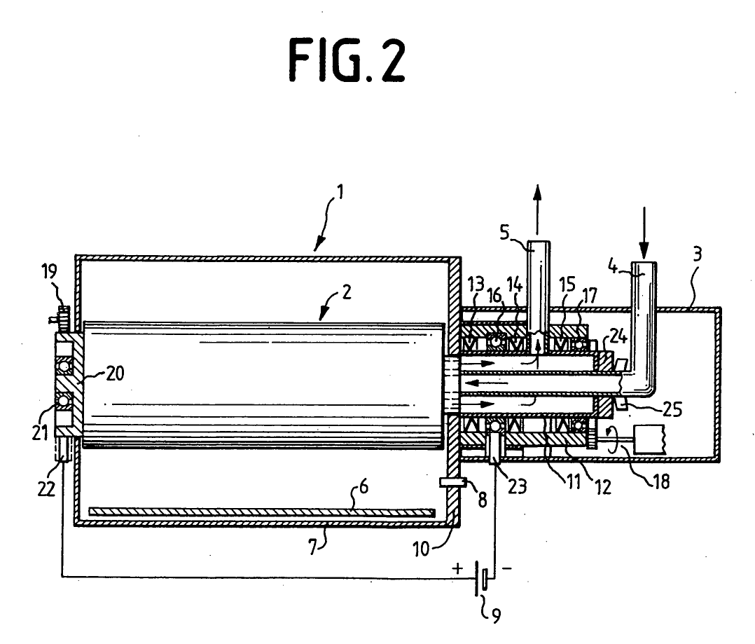

FIG. 2 an enlarged representation of the interface between a vacuum chamber and the atmosphere,

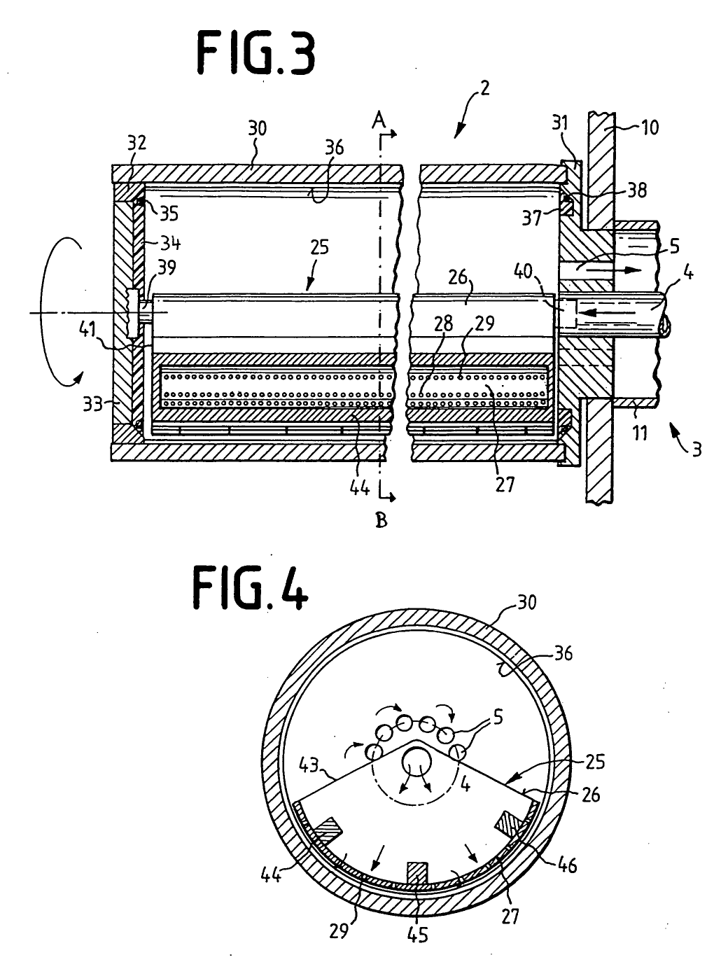

FIG. 3 a longitudinal section through a target tube,

FIG. 4 a cross section through the target tube according to FIG. 3.

The schematic representation of FIG. 1 shows a vacuum chamber 1, whose front portion is broken open revealing a tube cathode 2. This tube cathode can be set into rotational motion by a driving unit disposed in a connection fitting 3. On this connection fitting 3 are provided a fluid inflow 4 and a fluid outflow 5. Beneath the tube cathode 2 is disposed a substrate 6 to be coated, which either is placed in contact on a bottom 7 of the vacuum chamber 1 or can be moved over this bottom 7. By 8 is denoted a gas inflow opposite of which is located on the opposing side of the vacuum chamber 1 a gas outflow, not shown.

The tube cathode 2 is connected to the negative pole of a voltage source 9, here shown as a DC voltage source. The positive pole of the voltage source 9 is connected to the bottom 7 of the vacuum chamber 1. It is understood that, instead of a DC voltage source, an AC voltage source can also be provided.

FIG. 2 depicts the vacuum chamber 1 in longitudinal section. Evident are again the tube cathode 2, the connection fitting 3 with the fluid inflow 4 and the fluid outflow 5, the substrate 6, the bottom 7, the gas inflow 8 and the DC voltage source 9. In addition, a receptacle wall 10 is evident. This receptacle wall 10 separates the vacuum obtaining in the vacuum chamber 1 from the atmosphere encompassing the connection fitting 3. In the connection fitting 3 is located a fluid tube 11, which includes the fluid inflow 4 and the fluid outflow 5. Disposed coaxially about the fluid tube 11 is a tube 12 comprised of an electrically non-conducting material. Between the two tubes 11 and 12 are disposed three sealing rings 13, 14, 15 and two bearing arrangements 16, 17. In front of the bearing arrangement 17 is located a rotary drive unit 18, rotating the tube cathode 2. A further rotary drive unit 19 is provided at the other end of the rotating cathode, at which a connection fitting 20 of the tube cathode 2 rests in a bearing 21. By 22, 23 are denoted current feeds to which are connected the poles of the DC voltage source 9.

In FIG. 3 the vacuum chamber 1 is omitted and essentially only the target tube 2 is shown in section. The vacuum chamber 1 is only indicated by its receptacle wall 10. Within the target tube 2 is disposed an inner body 25 comprising two upper obliquely disposed walls, of which in FIG. 3 only one wall 26 is shown. Beneath this oblique wall is evident a circular arc-form pan 27, which is provided with several holes 28, 29.

A tubular target 30 is supported with its one end in a receiving flange 31 and with its other end rests on a male fitting ring 32, which encompasses an end flange 33. In front of the end flange 33 is located a sealing plate 34 provided with a sealing ring 35, which abuts an elastic film 36. This film is developed cylindrically and extends parallel to the inside of target. By means of a sealing ring 37 comprising a rubber ring 38, film 36 is clamped in at its other end. The inner body 25 is stationarily supported on both sides with one connection fitting 39, 40 each, i.e. it does not take part in the rotational movement of the target 30. The cylindrical film 36, damped in at both sides, is the principal element of the invention. As the cooling fluid, for example water, is being introduced via the inlet 4—which extends up into the proximity of the end wall 41 of the inner body 25—into the inner body, it abuts against this end wall 41 and flows through the holes of the circular arc-form pan 27 downwardly onto film 36. With increasing quantity of the cooling fluid, it increasingly rises upwardly until it reaches the upper side of film 36. The liquid pressure now reaches a magnitude such that the film is firmly pressed onto the inside of the target. Hereby effective cooling of the target becomes possible.

The inner body 25 does not necessarily need to be fixedly supported. Rather, it can also be swivelled via a knee lever structure or the like, for example when exchanging the target.

FIG. 4 depicts a cross section A-B through the tube cathode 2. Evident are here the circular arc-form pan 27, walls 26, 43, inflow 4 and outflow 5. The outflow 5 is here comprised of several holes disposed in a circle. On the inside of the circular arc-form pan 27 are disposed three permanent magnets 44, 45, 46, which extend over the length of target 30.

The inner body 25 has diverse functions. It serves, for example, to ensure the uniform distribution of the fluid during the fluid intake and output. It incorporates the magnets 44 to 46. In case the tube cathode 2 is supported on one side, it absorbs in addition the pressure at the tube end through a counterbearing 39.

The flexible film 36 is implemented as a continuously open or unilaterally open inner-tube and at the particular end on a flange 31, 33 sealed off by a film sealing system 32, 34, 33; 37, 38. This makes the film mountable and exchangeable, and thereby allows access to the inner body 25.

During a target exchange the cooling fluid is drained, the film 36 released, and the target tube 30 can simply be pulled off. The film can be comprised of various materials, for example of rubber, synthetic material, metal, graphite fibers or glass fibers or of a combination of these materials. The critical issue is that the film is fluid-tight. The sealing at the film end can be adhered, welded, vulcanized or be implemented as O-rings.

1. Rotatable tube cathode for cathode sputtering, in which the tube cathode comprises a fluid cooling system and the fluid cooling means flows past the inner wall of a target or target carrier, characterized in that between the target carrier or the target (30) and the central longitudinal axis of the tube cathode (2) a cylindrical and elastic film (36) is provided.

2. Rotatable tube cathode as claimed in claim 1, characterized in that within the target (30) or target carrier at least one stationary magnet (44) is provided, which does not take part in the rotational movements of the tube cathode (2).

3. Rotatable tube cathode as claimed in claim 1, characterized in that the cylindrical and elastic film (36) encompasses an inner body (25), over which a cooling means is conducted.

4. Rotatable tube cathode as claimed in claim 1, characterized in that the cylindrical and elastic film (36) is connected with one flange (31, 33) at each of its two ends.

5. Rotatable tube cathode as claimed in claim 3, characterized in that the inner body (25) has a circular arc-form bottom (27), which is provided with holes (28, 29) for the passage of the cooling means.

6. Rotatable tube cathode as claimed in claim 5, characterized in that the circular arc-form bottom (27) supports magnets (44 to 46).

7. Rotatable tube cathode as claimed in claim 3, characterized in that a cooling means supply (4) in the form of a tube is provided, which extends from the side of the atmosphere into the inner body (25) and terminates shortly in front of a side wall (41) of the inner body (25).

8. Rotatable tube cathode as claimed in claim 1, characterized in that the space between the outer wall of the inner body (25) and the inner wall of the cylindrical and elastic film (36) serves as a cooling means flow-back space.

9. Rotatable tube cathode as claimed in claim 1, characterized in that the cylindrical and elastic film (36) is comprised of rubber, synthetic material, metal, graphite fiber, glass fiber or of combinations of these substances.

10. Rotatable tube cathode as claimed in claim 1, characterized in that the elastic film (36) is sealed off at its ends by adhesion, welding, vulcanization or via brings.
